(19) United States
(12) Patent Application Publication
(10) Pub. No.: US 2013/0146899 A1
(43) Pub. Date: Jun. 13, 2013

(54) CMOS SENSOR WITH IMAGE SENSING UNIT INTEGRATED THEREIN

(71) Applicants: Ying-Zong JUANG, Hsinchu City (TW); Hann-Huei Tsai, Hsinchu City (TW); Hsin-Hao Liao, Hsinchu City (TW); Chen-Fu Lin, Hsinchu City (TW)

(72) Inventors: Ying-Zong JUANG, Hsinchu City (TW); Hann-Huei Tsai, Hsinchu City (TW); Hsin-Hao Liao, Hsinchu City (TW); Chen-Fu Lin, Hsinchu City (TW)

(73) Assignee: National Chip Implementation Center National Applied Research Laboratories, Hsinchu City (TW)

(21) Appl. No.: 13/408,356

(22) Filed: Feb. 29, 2012

(30) Foreign Application Priority Data
Dec. 9, 2011 (TW) TW 100145436

(51) Int. Cl. H01L 33/02

(52) U.S. Cl. 257/80; 257/E33.055; 257/E31.111

(57) ABSTRACT

A complementary metal-oxide semiconductor (CMOS) sensor with an image sensing unit integrated therein is provided. The CMOS sensor includes a first substrate, a CMOS circuit, and a sensing device. The first substrate has the image sensing unit formed thereon. The CMOS circuit is disposed on the first substrate and has a receiving space. The sensing device is disposed in the receiving space. The image sensing unit is located at a position from which the image sensing unit can monitor the sensing device. Accordingly, the image sensing unit monitors the sensing device by sensing its image.

### BACKGROUND OF THE INVENTION

1. Technical Field

The present invention relates to complementary metal-oxide semiconductor (CMOS) sensors with an image sensing unit integrated therein, and more particularly, to a CMOS sensor for use with electronic products for detecting an operation, gas, biomedical molecule, etc.

2. Description of Related Art

Conventional complementary metal-oxide semiconductor (CMOS) micro electromechanical system (MEMS) sensors generate signals by employing an analog circuit to detect electrical variations related to capacitance; voltage, current, or resistance and caused by a MEMS sensing device in operation and then converting the electrical variations into electrical signals corresponding thereto. Hence, the conventional CMOS MEMS sensors have to be of a special detection structure designed and produced in a way that takes into account the electrical variations related to capacitance, voltage, current, or resistance and caused by the MEMS sensing device in operation. As a result, considerable limitations are imposed upon the downsizing of the conventional CMOS MEMS sensors.

Restricted to structural characteristics of the finished products manufactured by a standard CMOS process technique, the conventional CMOS MEMS sensors have a drawback—in the course of transmitting electrical signals which are converted from the electrical variations caused by the MEMS sensing device in operation and detected by the analog circuit, the electrical signals being transmitted are so weak that they are susceptible to interference from various noise and thus eventually get distorted. As a result, the sensitivity of the conventional CMOS MEMS sensors is lower than the sensitivity of MEMS sensors manufactured by a specific dedicated process designed in accordance with a MEMS structure.

Due to the aforesaid limitations, such as the necessity of a special detection structure designed and produced in a way that takes into account the electrical variations related to capacitance, voltage, current, or resistance and caused by the MEMS sensing device in operation, and the low sensitivity of the conventional CMOS MEMS sensors manufactured by a standard CMOS process, it is difficult to simplify a manufacturing process of the conventional CMOS MEMS sensors, thereby resulting in an unfavorable factor in the mass production of the conventional CMOS MEMS sensors.

### SUMMARY OF THE INVENTION

The present invention provides a complementary metal-oxide semiconductor (CMOS) sensor with an image sensing unit integrated therein, comprising a first substrate, a CMOS circuit, and a sensing device. An objective of the present invention is to enable an image sensing unit to monitor a sensing device by sensing its image.

The present invention provides a complementary metal-oxide semiconductor (CMOS) sensor with an image sensing unit integrated therein, comprising: a first substrate having an image sensing unit formed thereon, the image sensing unit being a CMOS device; a CMOS circuit disposed on the first substrate to form a receiving space; and a sensing device disposed in the receiving space and electrically connected to the CMOS circuit, the sensing device being a CMOS MEMS sensing device; wherein the image sensing unit is located at a position from which the image sensing unit monitors the sensing device.

The present invention also provides a complementary metal-oxide semiconductor (CMOS) sensor with an image sensing unit integrated therein, comprising: a first substrate; a CMOS circuit disposed on the first substrate to form a receiving space; a sensing device disposed in the receiving space and electrically connected to the CMOS circuit, the sensing device being a CMOS MEMS sensing device; and a second substrate coupled to the CMOS circuit and having an image sensing unit formed thereon and located at a position opposite to the first substrate, wherein the image sensing unit is a CMOS device located at a position from which the image sensing unit monitors the sensing device.

The present invention still provides a complementary metal-oxide semiconductor (CMOS) sensor with an image sensing unit integrated therein, comprising: a first substrate; a CMOS circuit disposed on the first substrate to form a receiving space; a sensing device disposed in the receiving space and electrically connected to the CMOS circuit, the sensing device being a CMOS MEMS sensing device; and a second substrate disposed beside the first substrate and having an image sensing unit formed thereon, the image sensing unit being a CMOS device located at a position from which the image sensing unit monitors the sensing device.

Implementation of the present invention at least involves inventive steps as follows:

1. dispensing with an additional electrical variation detection structure and thus downsizing a CMOS sensor;

2. reducing greatly noise interference in weak signals generated by a CMOS MEMS sensing device and being transmitted and thus enhancing the sensitivity of the CMOS sensor; and

3. allowing an image sensing unit, a CMOS circuit, and a CMOS MEMS sensing device to be produced by a CMOS process, making process integration easy, and simplifying the process, so as to facilitate production.

The detailed features and advantages of the present invention will be described in detail with reference to the preferred embodiment so as to enable persons skilled in the art to gain insight into the technical disclosure of the present invention, implement the present invention accordingly, and readily understand the objectives and advantages of the present invention by perusal of the contents disclosed in the specification, the claims, and the accompanying drawings.

### BRIEF DESCRIPTION OF THE SEVERAL VIEWS OF THE DRAWINGS

FIG. 1A is a side cross-sectional view of a complementary metal-oxide semiconductor (CMOS) sensor with an image sensing unit integrated therein according to an embodiment of the present invention;

FIG. 1B is a front cross-sectional view of a CMOS sensor with an image sensing unit integrated therein according to an embodiment of the present invention;

FIG. 1C is a top view of a CMOS sensor with an image sensing unit integrated therein according to an embodiment of the present invention;

FIG. 2 is a cross-sectional view of the CMOS sensor further comprising an LED module according to an embodiment of the present invention;

FIG. 3 is a cross-sectional view of the CMOS sensor further comprising a package according to an embodiment of the present invention;

FIG. 4 is a cross-sectional view of the CMOS sensor comprising a first substrate and an opposing second substrate coupled thereto according to an embodiment of the present invention;

FIG. 5 is a cross-sectional view of the CMOS sensor comprising a first substrate and an opposing second substrate coupled thereto and further comprising an LED according to an embodiment of the present invention;

FIG. 6 is a cross-sectional view of the CMOS sensor comprising a first substrate and a second substrate disposed beside the first substrate according to an embodiment of the present invention;

FIG. 7 is a cross-sectional view of the CMOS sensor comprising a first substrate and a second substrate disposed beside the first substrate and further comprising an LED module according to an embodiment of the present invention; and

FIG. 8 is a cross-sectional view of the CMOS sensor comprising a first substrate and a second substrate disposed beside the first substrate and further comprising a package according to an embodiment of the present invention.

### DETAILED DESCRIPTION OF THE EMBODIMENTS OF THE INVENTION

### First Embodiment

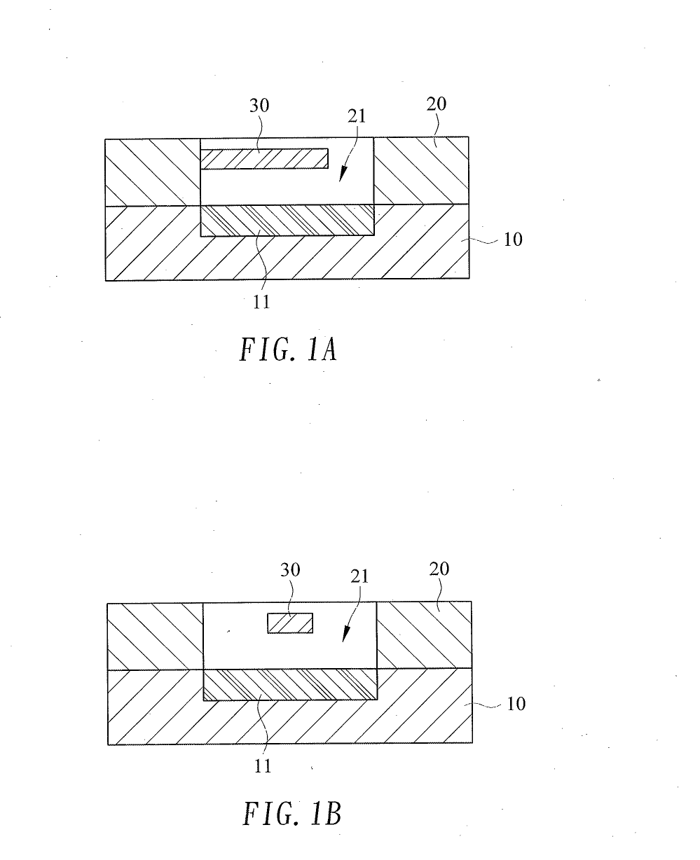

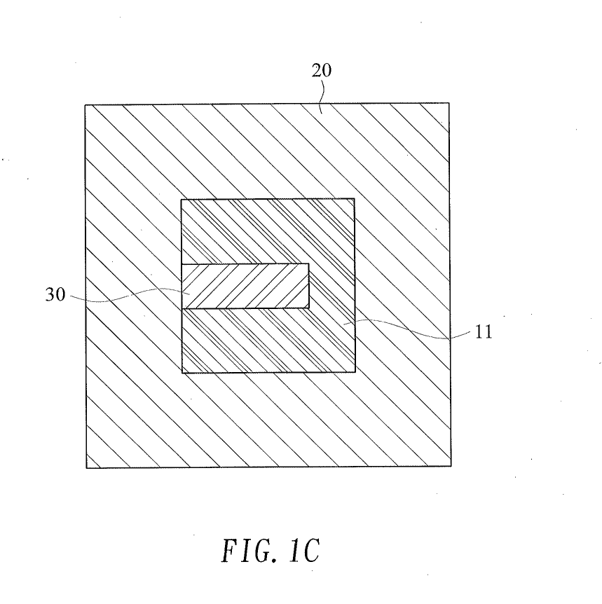

Referring to FIG. 1A through FIG. 1C, in this embodiment, a complementary metal-oxide semiconductor (CMOS) sensor with an image sensing unit integrated therein comprises a first substrate 10, a CMOS circuit 20, and a sensing device 30.

The first substrate 10 serves as a base, such that the CMOS circuit 20 is formed on and fixed to the base. From the perspective of a material, the first substrate 10 can be a silicon substrate. An image sensing unit 11 is formed on the first substrate 10 for monitoring an operation or a superficial state of the sensing device 30. The image sensing unit 11 is a CMOS device manufactured by a general CMOS process. The image sensing unit 11 is an image sensor or a light detector, such as a CMOS image sensor (CIS), a visible light detector, or an infra-red detector. The image sensing unit 11 is positioned in a manner that an image sensing region thereof faces the sensing device 30, and is located at a position from which the image sensing unit 11 can monitor the sensing device 30, such that the image sensing unit 11 can monitor an operation state of the sensing device 30 by sensing an image or detecting a variation of brightness.

The CMOS circuit 20 is disposed on the first substrate 10 for receiving a signal from the image sensing unit 11, processing the received signal, and outputting the processed signal. Hence, depending on its purpose, the CMOS circuit 20 is an analog circuit, a digital circuit, a memory circuit, a high-frequency circuit, or a high-voltage circuit. The CMOS circuit 20 forms above the image sensing region of the image sensing unit 11 a receiving space 21 for receiving the sensing device 30. Also, the CMOS circuit 20 provides a mechanism for fixing the sensing device 30 in place.

The sensing device 30 is disposed in the receiving space 21 formed from the CMOS circuit 20, and is electrically connected to the CMOS circuit 20 so as to receive the required power. The sensing device 30 is a cantilever structure. The sensing device 30 has one end connected to the CMOS circuit 20 only and the other end freely received in the receiving space 21. The sensing device 30 is a CMOS MEMS sensing device, such as a physical sensing device, a motion sensing device, an environment sensing device, or a biomedical sensing device. The CMOS circuit 20, the sensing device 30, and the image sensing unit 11 are CMOS devices and thus can be manufactured by the same CMOS process. An initial substrate undergoes a standard CMOS process. For example, the initial substrate undergoes a doping process, an oxidation process, and a thin-film process, and then undergoes a lithographic process, an etching process, and a polishing process, such that the first substrate 10, the CMOS circuit 20, the sensing device 30, and the image sensing unit 11 are formed in the initial substrate, thereby simplifying the CMOS process to facilitate mass production.

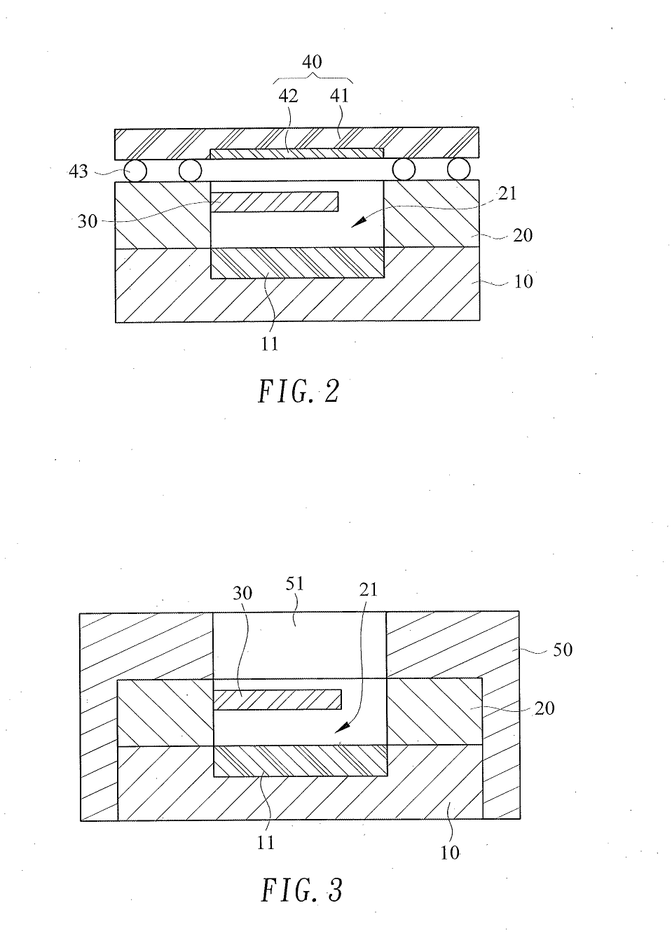

Referring to FIG. 2, in this embodiment, the CMOS sensor further comprises an LED module 40 for providing irradiation required for the image sensing unit 11 to monitor an image of the sensing device 30. The LED module 40 comprises a third substrate 41 and at least one LED 42. The LED 42 is formed on the third substrate 41. A required circuit is formed on a surface of the third substrate 41, wherein the surface of the third substrate 41 faces the CMOS circuit 20, so as to provide a structure required for electrical connection with the CMOS circuit 20 and supply the power required for the operation of the LED 42. To gain access to power supply required for its operation, the LED module 40 is electrically connected to the CMOS circuit 20 via solder balls 43 and located at a position for facing the light emitted from the sensing device 30, such that the light emitted from the LED module 40 can be smoothly projected onto the sensing device 30 and sensed by the image sensing unit 11.

Referring to FIG. 3, in this embodiment, the CMOS sensor further comprises a package 50. The package 50 encloses the CMOS sensor; for example, the package 50 covers the periphery of the first substrate 10 and covers the CMOS circuit 20 laterally and from above. The package 50 further comprises a light-transmissive portion 51. The light-transmissive portion 51 is an opening formed on the package 50, or is a device made of a transparent plastic and coupled to the package 50. The light-transmissive portion 51 corresponds in position to the sensing device 30 and the image sensing unit 11. For example, the light-transmissive portion 51 is disposed above the receiving space 21 and the sensing device 30, such that external environmental light passes through the light-transmissive portion 51 to enter the CMOS sensor and irradiate the sensing device 30, thereby allowing the image sensing unit 11 to monitor an operation or a superficial state of the sensing device 30.

### Second Embodiment

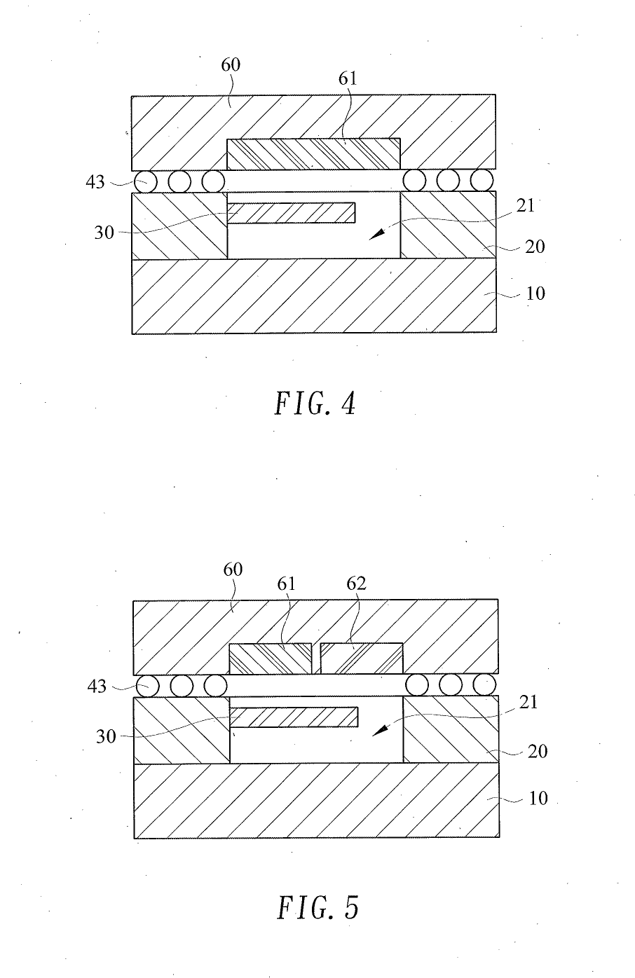

Referring to FIG. 4, in this embodiment, a CMOS sensor with an image sensing unit integrated therein comprises a first substrate 10, a CMOS circuit 20, a sensing device 30, and a second substrate 60.

The first substrate 10 serves as a base, such that the CMOS circuit 20 is formed on and fixed to the base. From the perspective of a material, the first substrate 10 can be a silicon substrate.

The CMOS circuit 20 is disposed on the first substrate 10. Depending on its purpose, the CMOS circuit 20 is an analog circuit, a digital circuit, a memory circuit, a high-frequency circuit, or a high-voltage circuit. The CMOS circuit 20 forms a receiving space 21 for receiving the sensing device 30. An opening of the receiving space 21 faces the second substrate 60. The CMOS circuit 20 provides a mechanism for fixing the sensing device 30 in place.

The sensing device 30 is disposed in the receiving space 21 formed from the CMOS circuit 20, and is electrically connected to the CMOS circuit 20 so as to receive the required power. The sensing device 30 is a cantilever structure. The sensing device 30 has one end connected to the CMOS circuit 20 only and the other end freely received in the receiving space 21. The sensing device 30 is a CMOS MEMS sensing device, such as a physical sensing device, a motion sensing device, an environment sensing device, or a biomedical sensing device.

The second substrate 60 is coupled to the CMOS circuit 20 and is opposite to the first substrate 10. For the perspective of a material, the second substrate 60 can be a silicon substrate. The second substrate 60 has a plurality of circuit structures disposed therein and is electrically connected to the CMOS circuit 20 via a plurality of solder balls 43 to supply the power required for devices on the second substrate 60 and provide a path of signal transmission.

An image sensing unit 61 is formed on the second substrate 60 for monitoring an operation or a state of the sensing device 30. The image sensing unit 61 is a CMOS device and thus can be manufactured by a general CMOS process. The image sensing unit 61 is an image sensor or a light detector, such as a CMOS image sensor (CIS), a visible light detector, or an infra-red detector, and is located at a position from which the image sensing unit 61 can monitor the sensing device 30, such that the image sensing unit 61 can monitor an operation state of the sensing device 30 by sensing an image or detecting a variation of brightness.

The CMOS circuit 20 and the sensing device 30 are CMOS devices and thus can be manufactured by the same CMOS process. An initial substrate undergoes a standard CMOS process. For example, the initial substrate undergoes a doping process, an oxidation process, and a thin-film process, and then undergoes a lithographic process, an etching process, and a polishing process, such that the first substrate 10, the CMOS circuit 20, and the sensing device 30 are formed in the initial substrate, thereby simplifying the CMOS process to facilitate mass production.

Referring to FIG. 5, the second substrate 60 further has an LED 62 disposed thereon and located at a position from which the LED 62 provides irradiation to the sensing device 30. For example, the LED 62 is disposed on the surface of the second substrate 60 and positioned above the receiving space 21 and the sensing device 30 for providing irradiation required for the image sensing unit 61 to monitor an image of the sensing device 30, such that the light emitted from the LED 62 can be smoothly projected onto the sensing device 30 and monitored by the image sensing unit 61.

### Third Embodiment

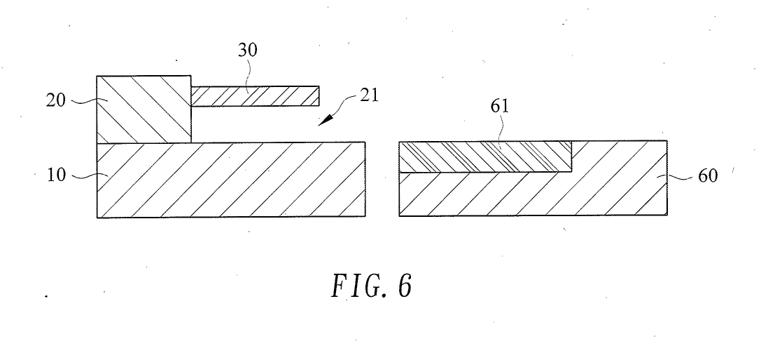

Referring to FIG. 6, in this embodiment, a CMOS sensor with an image sensing unit integrated therein comprises a first substrate 10, a CMOS circuit 20, a sensing device 30, and a second substrate 60.

The first substrate 10 serves as a base, such that the CMOS circuit 20 is formed on and fixed to the base. From the perspective of a material, the first substrate 10 can be a silicon substrate.

The CMOS circuit 20 is disposed on the first substrate 10. Depending on its purpose, the CMOS circuit 20 is an analog circuit, a digital circuit, a memory circuit, a high-frequency circuit, or a high-voltage circuit. The CMOS circuit 20 is formed at a lateral portion of the surface of the first substrate 10 to form a receiving space 21 for receiving and fixing the sensing device 30. The receiving space 21 has an open end facing the second substrate 60.

The sensing device 30 is disposed in the receiving space 21 formed from the CMOS circuit 20, and is electrically connected to the CMOS circuit 20 so as to gain access to the required power supply. The sensing device 30 has one end connected to the CMOS circuit 20 only and the other end freely received in the receiving space 21 and extended in the direction of the second substrate 60 to form a cantilever structure. The sensing device 30 is a CMOS MEMS sensing device, such as a physical sensing device, a motion sensing device, an environment sensing device, or a biomedical sensing device.

The second substrate 60 is a silicon substrate. The second substrate 60 is disposed beside the first substrate 10. An image sensing unit 61 is formed on the second substrate 60 for monitoring an operation or a state of the sensing device 30. The image sensing unit 61 is a CMOS device and thus can be manufactured by a general CMOS process. The image sensing unit 61 is an image sensor or a light detector, such as a CMOS image sensor (CIS), a visible light detector, or an infra-red detector. The image sensing unit 61 is located at a position from which the image sensing unit 61 can monitor the sensing device 30. For example, the image sensing unit 61 is positioned in the vicinity of the open end of the receiving space 21, and thus the image sensing unit 61 can monitor an operation state of the sensing device 30 by sensing an image or by detecting a variation of brightness.

The CMOS circuit 20 and the sensing device 30 are CMOS devices and thus can be manufactured by the same CMOS process. An initial substrate undergoes a standard CMOS process. For example, the initial substrate undergoes a doping process, an oxidation process, and a thin-film process, and then undergoes a lithographic process, an etching process, and a polishing process, such that the first substrate 10, the CMOS circuit 20, and the sensing device 30 are formed in the initial substrate, thereby simplifying the CMOS process to facilitate mass production.

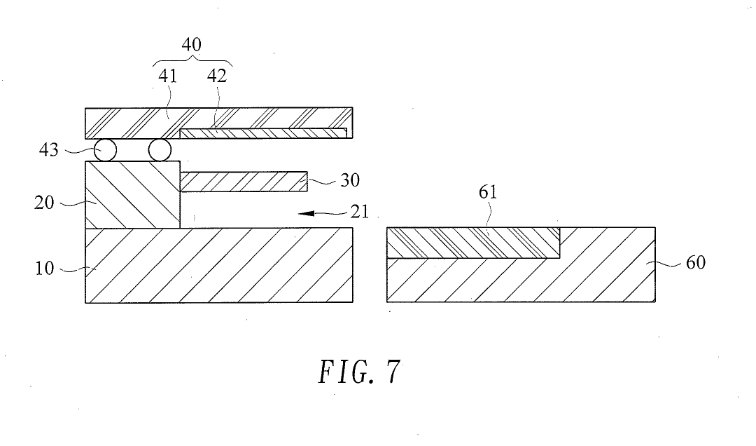

Referring to FIG. 7, in this embodiment, the CMOS sensor further comprises an LED module 40. The LED module 40 comprises a third substrate 41 and at least one LED 42. The LED 42 is formed on the third substrate 41. The LED module 40 provides irradiation required for the image sensing unit 61 to monitor an image of the sensing device 30. A required circuit is formed on a surface of the third substrate 41, wherein the surface of the third substrate 41 faces the CMOS circuit 20, so as to provide a structure required for electrical connection with the CMOS circuit 20 and supply the power required for the operation of the LED 42. To gain access to power supply required for its operation, the LED module 40 is electrically connected to the CMOS circuit 20 via solder balls 43 and located at a position for facing the light emitted from the sensing device 30, such that the light emitted from the LED module 40 can be smoothly projected onto the sensing device 30 and monitored by the image sensing unit 61.

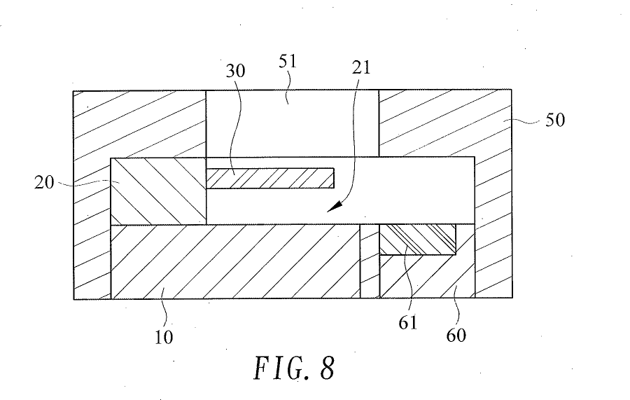

Referring to FIG. 8, in this embodiment, the CMOS sensor further comprises a package 50. The package 50 encloses the CMOS sensor; for example, the package 50 covers the periphery of the first substrate 10, covers the CMOS circuit 20 laterally and from above, and covers the second substrate 60 peripherally and from above, but does not cover the area between the sensing device 30 and the image sensing unit 61. The package 50 further comprises a light-transmissive portion 51. The light-transmissive portion 51 is located at a position conducive to providing external environmental light to the sensing device 30. For example, the light-transmissive portion 51 is disposed above the receiving space 21 and the sensing device 30, such that external environmental light can irradiate the sensing device 30. The light-transmissive portion 51 is an opening formed on the package 50, or is a device made of a transparent plastic and coupled to the package 50, such that the package 50 has a light-transmissive portion, thereby allowing the image sensing unit 61 to monitor an operation or a state of the sensing device 30.

The above description indicates: in this embodiment, the image sensing units 11, 61 perform image monitoring on the sensing device 30, such that the CMOS sensor dispenses with an additional electrical variation detection structure, and thus it is feasible to downsize the CMOS sensor; due to the integration of the CMOS circuit 20, the sensing device 30, and the image sensing units 11, 61, signals resulting from the monitoring of an operation or a superficial state of the sensing device 30 by the image sensing units 11, 61 can be transmitted by the shortest distance to the CMOS circuit 20 and processed therein, such that a very short path of transmission of the signals greatly reduces noise interference in the signal in the course of transmission and enhances the sensitivity of the CMOS sensor; the CMOS circuit 20, the sensing device 30, and the image sensing units 11, 61 are manufactured by a CMOS process, thereby simplifying the process to facilitate mass production.

The features of the present invention are disclosed above by the preferred embodiment to allow persons skilled in the art to gain insight into the contents of the present invention and implement the present invention accordingly. The preferred embodiment of the present invention should not be interpreted as restrictive of the scope of the present invention. Hence, all equivalent modifications or amendments made to the aforesaid embodiment should fall within the scope of the appended claims.

What is claimed is:

1. A complementary metal-oxide semiconductor (CMOS) sensor with an image sensing unit integrated therein, comprising:
a first substrate having an image sensing unit formed thereon, the image sensing unit being a CMOS device;
a CMOS circuit disposed on the first substrate to form a receiving space; and
a sensing device disposed in the receiving space and electrically connected to the CMOS circuit, the sensing device being a CMOS MEMS sensing device;
wherein the image sensing unit is located at a position from which the image sensing unit monitors the sensing device.

2. The CMOS sensor of claim 1, wherein the first substrate is a silicon substrate.

3. The CMOS sensor of claim 1, wherein the image sensing unit is one of an image sensor and a light detector.

4. The CMOS sensor of claim 1, wherein the CMOS circuit is one of an analog circuit, a digital circuit, a memory circuit, a high-frequency circuit, and a high-voltage circuit.

5. The CMOS sensor of claim 1, wherein the sensing device is one of a physical sensing device, a motion sensing device, an environment sensing device, and a biomedical sensing device.

6. The CMOS sensor of claim 1, further comprising an LED module electrically connected to the CMOS circuit and facing a light-emitting position of the sensing device.

7. The CMOS sensor of claim 1, further comprising a package enclosing the CMOS sensor and having a light-transmissive portion located at a position from which the light-transmissive portion provides external environmental light to the sensing device.

8. A complementary metal-oxide semiconductor (CMOS) sensor with an image sensing unit integrated therein, comprising:
a first substrate;
a CMOS circuit disposed on the first substrate to form a receiving space;
a sensing device disposed in the receiving space and electrically connected to the CMOS circuit, the sensing device being a CMOS MEMS sensing device; and
a second substrate coupled to the CMOS circuit and having an image sensing unit formed thereon and located at a position opposite to the first substrate, wherein the image sensing unit is a CMOS device located at a position from which the image sensing unit monitors the sensing device.

9. The CMOS sensor of claim 8, wherein one of the first substrate and the second substrate is a silicon substrate.

10. The CMOS sensor of claim 8, wherein the CMOS circuit is one of an analog circuit, a digital circuit, a memory circuit, a high-frequency circuit, and a high-voltage circuit.

11. The CMOS sensor of claim 8, wherein the sensing device is one of a physical sensing device, a motion sensing device, an environment sensing device, and a biomedical sensing device.

12. The CMOS sensor of claim 8, wherein the image sensing unit is one of an image sensor and a light detector.

13. The CMOS sensor of claim 8, wherein the second substrate further has an LED disposed thereon and located at a position from which from the LED provides irradiation to the sensing device.

14. A complementary metal-oxide semiconductor (CMOS) sensor with an image sensing unit integrated therein, comprising:
a first substrate;
a CMOS circuit disposed on the first substrate to form a receiving space;
a sensing device disposed in the receiving space and electrically connected to the CMOS circuit, the sensing device being a CMOS MEMS sensing device; and
a second substrate disposed beside the first substrate and having an image sensing unit formed thereon, the image sensing unit being a CMOS device located at a position from which the image sensing unit monitors the sensing device.

15. The CMOS sensor of claim 14, wherein one of the first substrate and the second substrate is a silicon substrate.

16. The CMOS sensor of claim 14, wherein the CMOS circuit is one of an analog circuit, a digital circuit, a memory circuit, a high-frequency circuit, and a high-voltage circuit.

17. The CMOS sensor of claim 14, wherein the sensing device is one of a physical sensing device, a motion sensing device, an environment sensing device, and a biomedical sensing device.

18. The CMOS sensor of claim 14, wherein the image sensing unit is one of an image sensor and a light detector.

19. The CMOS sensor of claim 14, further comprising an LED module electrically connected to the CMOS circuit and facing a light-emitting position of the sensing device.

20. The CMOS sensor of claim 14, further comprising a package enclosing the CMOS sensor and having a light-transmissive portion located at a position from which the light-transmissive portion provides external environmental light to the sensing device.
